(19) United States
(12) Patent Application Publication
(10) Pub. No.: US 2013/0153272 A1
(43) Pub. Date: Jun. 20, 2013

(54) PRINTED CIRCUIT BOARD

(71) Applicants: HSING-HUI CHIU, Tu-Cheng (TW); PEI-JYUN SU, Tu-Cheng (TW); SZE-YU LIN, Tu-Cheng (TW)

(72) Inventors: HSING-HUI CHIU, Tu-Cheng (TW); PEI-JYUN SU, Tu-Cheng (TW); SZE-YU LIN, Tu-Cheng (TW)

(73) Assignee: HON HAI PRECISION INDUSTRY CO., LTD., Tu-Cheng (TW)

(21) Appl. No.: 13/598,842

(22) Filed: Aug. 30, 2012

(30) Foreign Application Priority Data
Dec. 16, 2011 (TW) 100146969

(51) Int. Cl. H05K 1/09

(52) U.S. Cl. 174/257

(57) ABSTRACT

A printed circuit board includes a top layer, a bottom layer, and a mounting hole vertically extending through the top layer and the bottom layer. A first copper ring is located on a top surface of the top layer and around the mounting hole. A second copper ring is located a bottom surface of the bottom layer and around the mounting hole. A number of first pads are positioned on the first copper ring. A number of second pads are positioned on the second copper ring. The first and second copper rings are covered with solder mask, but the first and second pads are not covered with the solder mask.

### BACKGROUND

1. Technical Field

The present disclosure relates to a printed circuit board (PCB).

2. Description of Related Art

A PCB is mounted to a chassis of an electronic device, such as a computer, with screws. If the screws are over tightened, the PCB may be damaged. Additionally, if the surfaces of the PCB are coated with organic solder preservatives, pads of the screw holes of the PCB are made of bare copper. However, the bare copper is susceptible to oxidation. Therefore, performance of the PCB may be affected.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a partial, isometric view of a printed circuit board (PCB) in accordance with an exemplary embodiment of the present disclosure, wherein the PCB includes a top layer and a bottom layer.

FIG. 2 is a cross-sectional view taken along the line II-II of FIG. 1.

FIG. 3 is an isometric view of a model board used to form a plurality of pads on one of the top layer and the bottom layer of the PCB of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

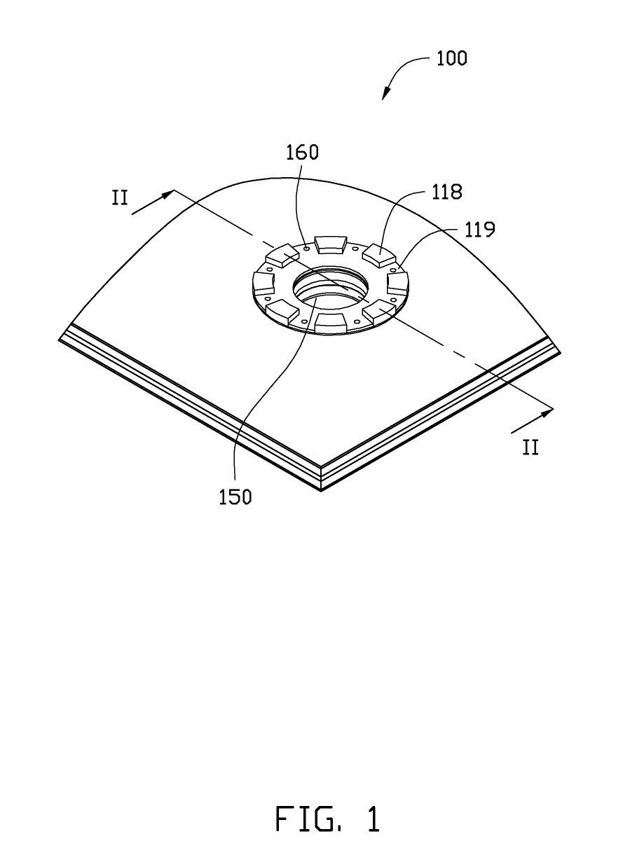

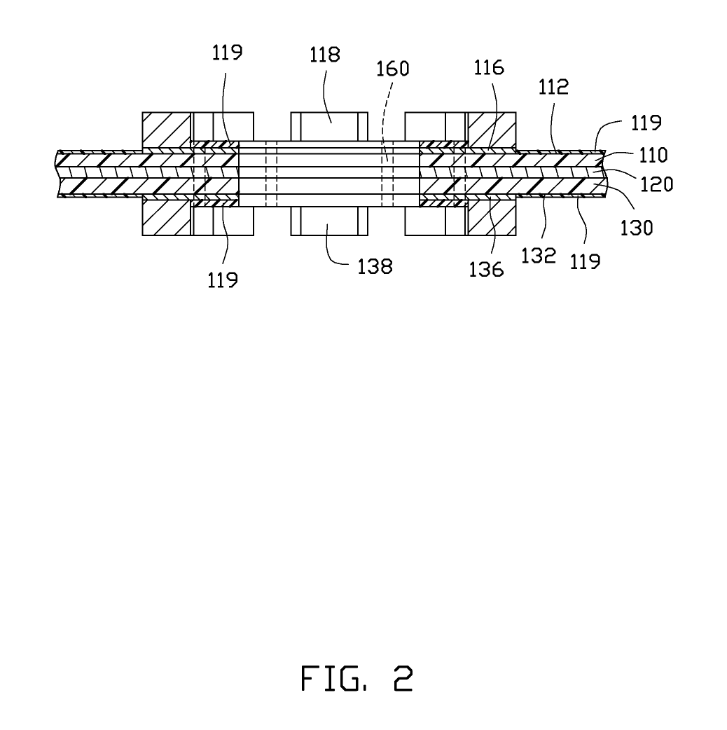

Referring to FIGS. 1 and 2, an exemplary embodiment of a printed circuit board (PCB) 100 is shown. The PCB 100 includes a top layer 110, a bottom layer 130, a ground layer 120 sandwiched between the top layer 110 and the bottom layer 130, and a mounting hole 150 vertically extending through the PCB 100. In one embodiment, each of the top layer 110 and the bottom layer 130 is an insulation layer, the mounting hole 150 is a non-plated through hole. It may be understood that the PCB 100 also includes other layers, such as a power layer and a signal layer. These other layers fall within well-known technologies, and are therefore not described here.

An annular first copper ring 116 is located on a top surface 112 of the top layer 110 and around the mounting hole 150. An annular second copper ring 136 is located on a bottom surface 132 of the bottom layer 130 and around the mounting hole 150. A plurality of first pads 118 is positioned on the first copper ring 116 and there is an interval between every two adjacent first pads 118. A plurality of second pads 138 is positioned on the second copper ring 136 and there is an interval between every two adjacent second pads 138. The first copper ring 116 is covered with solder mask 119, but the first pads 118 are not. The second copper ring 136 is covered with the solder mask 119, but the second pads 138 are not. In one embodiment, the inner diameter of each of the first copper ring 116 and the second copper ring 136 is equal to the diameter of the mounting hole 150. A shape and area of the first copper ring 116 is similar with the shape and area of the second copper ring 136. In addition, the shape and area of each first pad 118 is similar with the shape and area of a corresponding second pad 138. The first copper ring 116 aligns with the second copper ring 136, and each first pad 118 aligns with a corresponding second pad 138.

A plurality of conductive through holes 160 extends through the PCB 100. Each through hole 160 is defined in an interval between two adjacent first pads 118, and coated with conductive material and electrically connected to the first copper ring 116, the second copper ring 136 and the ground layer 120. The first copper ring 116 and the second copper ring 136 are electrically connected to the ground layer 120 through the through holes 160.

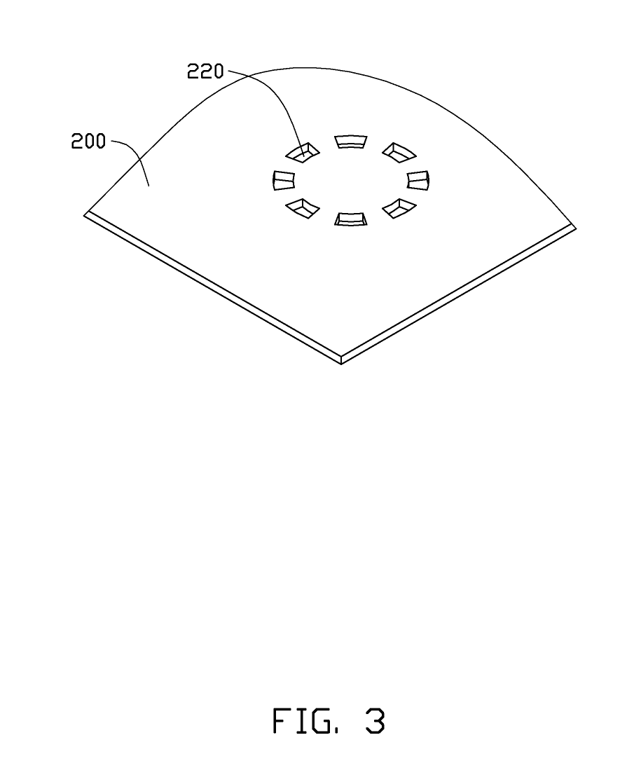

Referring to FIG. 3, in one embodiment, the first pads 118 are formed by the following method. A plurality of openings 220 is defined in a model board 200 along a circle corresponding to the first copper ring 116. The model board 200 covers the top surface 112 of the PCB 100, and is coated with solder paste. The solder paste is coated on the first copper ring 116 through the openings 220. The model board 200 is then removed from the PCB 100. The solder paste is mounted on the first copper ring 116 in the form of the first pads 118, after reflow soldering. The process of each second pad 138 being formed is similar with process of each first pad being 118 formed, and therefore is not repeated here.

In assembly, a mounting element (not shown), such as a screw, is employed to mount the PCB 100 to a chassis of an electronic device, such as a server, a computer, or a refrigerator. In detail, the mounting element extends through the mounting hole 150 from the top surface 112 of the PCB 100, and is engaged in a corresponding mounting portion of the chassis of the electronic device. The first pads 118 contact the mounting element, the second pads 138 contact the mounting portion of the chassis of the electronic device. Because the hardness of the first pads 118 is greater than the hardness of the first copper ring 116, and the hardness of the second pads 138 is greater than the hardness of the second copper ring 136. The first copper ring 116 and the second copper ring 136 are protected from damage that may be cause by an over tightening of the mounting element to the electronic device. Further, the solder mask 119 and the first pads 118 cover the first copper ring 116, the solder mask 119 and the second pads 138 cover the second copper ring 136, therefore, the first copper ring 116 and the second copper ring 136 are protected from oxidization. Additionally, noise of the ground layer 120 flows to ground through the through holes 160, the first copper ring 116, the first pads 118, the mounting element, and the chassis of the electronic device, and through the through holes 160, the second copper ring 136, the second pads 138, and the chassis of the electronic device, to prevent electromagnetic radiation.

In one embodiment, the first pads 118 are located on the first copper ring 116 along the outer circumference of the first copper ring 116, and there is an equal interval between every two adjacent first pads 118. The second pads 138 are located on the second copper ring 136 along the outer circumference of the second copper ring 136, and there is an equal interval between every two adjacent second pads 138. The solder mask 119 can protect the first copper ring 116 and the second copper ring 136, and provide electrical insulation. The model board 200 is a steel board. The openings 220 are formed by laser cutting, electroforming, or chemical etching, for example. In other embodiments, the number of the mounting holes 150 can be adjusted according to actual need. When the number of the mounting holes 150 is adjusted, the number of the first copper rings 116, the first pads 118, the second copper rings 136, the second pads 138, and the through holes 160 should be adjusted accordingly.

Even though numerous characteristics and advantages of the disclosure have been set forth in the foregoing description, together with details of the structure and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A printed circuit board (PCB), comprising:
a top layer comprising a top surface;
a bottom layer comprising a bottom surface;
a mounting hole vertically extending through the top layer and the bottom layer;
a first copper ring located on the top surface of the top layer and around the mounting hole;
a second copper ring located on the bottom surface of the bottom layer and around the mounting hole;
a plurality of first pads positioned on the first copper ring;
a plurality of second pads positioned on the second copper ring; and
solder mask covering the first and second copper rings, without covering the first and second pads.

2. The PCB of claim 1, wherein the first pads are located on the first copper ring along the outer circumference of the first copper ring, and there is an equal interval between every two adjacent first pads; the second pads are located on the second copper ring along the outer circumference of the second copper ring, and there is an equal interval between every two adjacent second pads.

3. The PCB of claim 2, wherein the first copper ring aligns with the second copper ring, and each first pad aligns with a corresponding second pad.

4. The PCB of claim 1, further comprising a ground layer sandwiched between the top layer and the bottom layer, wherein the mounting hole extends through the ground layer.

5. The PCB of claim 4, wherein each of the top layer and the bottom layer is an insulation layer.

6. The PCB of claim 5, further comprising a plurality of through holes extending through the top layer, the ground layer, and the bottom layer, wherein each through hole is defined in an interval between two adjacent first pads, and coated with conductive material and electrically connected to the first copper ring, the second copper ring, and the ground layer, the first copper ring and the second copper ring are electrically connected to the ground layer through the through holes.
